(19) United States
(12) Patent Application Publication
(10) Pub. No.: US 2013/0342969 A1
(43) Pub. Date: Dec. 26, 2013

(54) APPARATUS FOR SECURING AN ELECTRONIC DEVICE TO THE BODY OF A USER

(71) Applicant: Adem Krupich, Calgary (CA)

(72) Inventor: Adem Krupich, Calgary (CA)

(21) Appl. No.: 13/527,986

(22) Filed: Jun. 20, 2012

(51) Int. Cl. H05K 7/00

(52) U.S. Cl. 361/679.01

(57) ABSTRACT

The present invention relates generally to an apparatus for securing an electronic device to the body of a user and more particularly, relates to an apparatus that includes an elongated band that may be secured around a user's arm, wrist, or waist that also includes a pouch for holding an electronic device, a rechargeable battery that may be charged using either solar energy or electrical power, and an electrical connector cable to connect the rechargeable battery to the electronic device and provide a constant charge to the electronic device while the user is engaged in physical activities such as jogging, hiking, or biking.

### FIELD OF THE INVENTION

The present invention relates generally to devices for securing an electronic device to the body of a user, and more particularly, relating to an apparatus for securing an electronic device to an arm, wrist, or the like, of a user and which operates to provide power to operate and or charge the batteries of the electronic device while being worn on the user.

### BACKGROUND OF THE INVENTION

The use of personal electronic devices has become a ubiquitous and commonplace occurrence in our daily lives. Electronic devices such as cell phones, smart phones, portable music players, and digital cameras can be found everywhere and offer many features and functions that have proven invaluable in assisting us in keeping us connected to one another and in completing our daily tasks and activities. People have come to depend on their devices so heavily that they have almost become a necessity.

Despite advances in technology and the decreasing size of these electronic devices, carrying these devices may be cumbersome. For example, active individuals that enjoy outdoor activities such as jogging, hiking, or biking may choose to bring their electronic devices with them in order to remain accessible by phone, to listen to music, or to take photographs along the way. Carrying electronic devices while performing such activities may prove to be inconvenient and hazardous for the user if the user becomes distracted by the electronic device. Damage may also result to the electronic device, itself, if, for example, it is dropped along the way. Existing means for carrying these devices are well known in the art and include apparatus such as wristbands and armbands.

While wristbands and armbands may overcome the inconvenience of carrying one's electronic device, frequent and extended use of these devices also requires that the batteries powering these devices be replaced or charged frequently. Replacing batteries can be wasteful and expensive, and users do not generally carry spare batteries with them wherever they go. Rechargeable batteries, while better for the environment and more cost-efficient, also present an inconvenience because they must be charged frequently, if not daily, and often require the use of an electrical socket to provide electrical power to charge the electronic device. Therefore, the more an electronic device is used throughout the day, the more likely it will need to be charged, and recharging an electronic device while performing outdoor activities is not possible without some sort of power source. Loss of power in the electronic devices while performing these outdoor activities may not only prove inconvenient, but may also be dangerous, for example, if the user becomes injured or lost in the wilderness and requires assistance.

Accordingly, there is a need for an apparatus that will allow users to secure their electronic devices to their person, for example, during rigorous physical activity, while providing a means to maintain a constant charge to their electronic devices.

### SUMMARY OF THE INVENTION

The embodiments of the present invention address this need by providing an apparatus that will allow users to secure an electronic device to their person while ensuring the electronic device remains charged and powered.

Embodiments of the present invention also provide an apparatus for securing an electronic device to the body of a user that is constructed of a machine washable fabric.

Embodiments of the present invention also provide an apparatus for securing an electronic device to the body of a user that is constructed of a water resistant material.

Embodiments of the present invention also provide an apparatus for securing an electronic device to the body of a user that includes a solar energy operated power generator.

Embodiments of the present invention also provide an apparatus for securing an electronic device to the body of a user that includes an electrical connector to connect the solar energy operated power generator, on one end, to an electrical connector of the electronic device, on the second end, for electrically connecting the solar energy operated power generator and the electronic device to provide electrical power to the electronic device generated by said solar energy operated power generator.

Embodiments of the present invention also provide an apparatus for securing an electronic device to the body of a user that includes a solar energy operated power generator.

To achieve these and other advantages, in general, in one aspect, an apparatus for securing an electronic device to the body of a user is provided. The apparatus includes an elongated band having opposed first and second ends, an interior surface, and an exterior surface. A band end engagement mechanism is disposed proximate to the first end of the elongated band and operates to detachably secure together the first and second ends of the elongated band. A pouch for receiving an electronic device is the elongated band and includes an internal cavity that removably receives and conforms to the shape of an electronic device disposed therein. The pouch includes a window that registers with a control screen of the electronic device and permitting user access through the window to the control screen when the electronic device is received by the internal cavity. A solar energy operated power generator is supported by elongated band and an electrical connector cable is configured to connect the solar energy operated power generator to an electronic device to provide electrical energy from the solar energy operated power generator to the electronic device.

In general, in another aspect, an apparatus for holding an electronic device and securing the electronic device to the body of a user is provided. The apparatus includes an elongated band configured to encircle a body portion of a user and has opposed first and second ends and an exterior surface that faces in a general direction outwardly from the body of a user when the elongated band is secured to the user. A band end engagement mechanism is disposed proximate to the first end of the elongated band and operates to detachably secure together the first and second ends of the elongated band. An electronic device receiving pouch is disposed on the exterior surface of the elongated band and defines an interior cavity and an opening into the interior cavity through which an electronic device may be passed to insert the electronic device into the interior cavity. The interior cavity removably receives and conforms to an electronic device disposed therein. A solar energy operated power generator is disposed on the exterior surface of the elongated band and operates to provide electrical power for operating the electronic device and charging a rechargeable battery of the electronic device. An electrical cable is connectable at one end to the solar energy operated power generator and connectable at a second end to an electrical connector of the electronic device for electrically connecting the electronic device and the solar energy operated power generator to provide electrical power to the electronic device generated by the solar energy operated power generator.

There has thus been outlined, rather broadly, the more important features of the invention in order that the detailed description thereof that follows may be better understood and in order that the present contribution to the art may be better appreciated.

Numerous objects, features, and advantages of the present invention will be readily apparent to those of ordinary skill in the art upon a reading of the following detailed description of presently preferred, but nonetheless illustrative, embodiments of the present invention when taken in conjunction with the accompanying drawings. The invention is capable of other embodiments and of being practiced and carried out in various ways. Also, it is to be understood that the phraseology and terminology employed herein are for the purpose of descriptions and should not be regarded as limiting.

As such, those skilled in the art will appreciate that the conception, upon which this disclosure is based, may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

For a better understanding of the invention, its operating advantages and the specific objects attained by its uses, reference should be had to the accompanying drawings and descriptive matter in which there are illustrated embodiments of the invention.

### BRIEF DESCRIPTION OF THE DRAWINGS

The following drawings illustrate by way of example and are included to provide further understanding of the invention for the purpose of illustrative discussion of the embodiments of the invention. No attempt is made to show structural details of the embodiments in more detail than is necessary for a fundamental understanding of the invention, the description taken with the drawings making apparent to those skilled in the art how the several forms of the invention may be embodied in practice. Identical reference numerals do not necessarily indicate an identical structure. Rather, the same reference numeral may be used to indicate a similar feature of a feature with similar functionality. In the drawings:

FIG. 1 is a perspective view of an embodiment of the apparatus for securing an electronic device to the body of a user constructed in accordance with the principles of the present invention illustrating the apparatus in-use and worn about an arm of a user;

FIG. 2 is a front elevation view of an embodiment of the apparatus for securing an electronic device to the body of a user constructed in accordance with the principles of the present invention;

FIG. 3 is an exploded front elevation view of the apparatus for securing an electronic device to the body of a user of FIG. 2;

FIG. 4 is an exploded bottom plan view of the apparatus for securing an electronic device to the body of a user of FIG. 2; and

FIG. 5 is an exploded top plan view of the apparatus for securing an electronic device to the body of a user of FIG. 2.

### DETAILED DESCRIPTION OF THE INVENTION

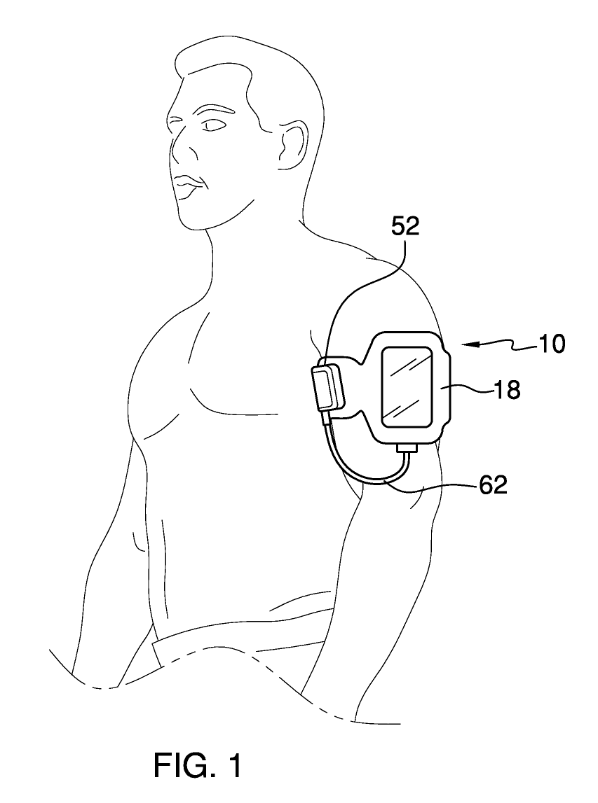

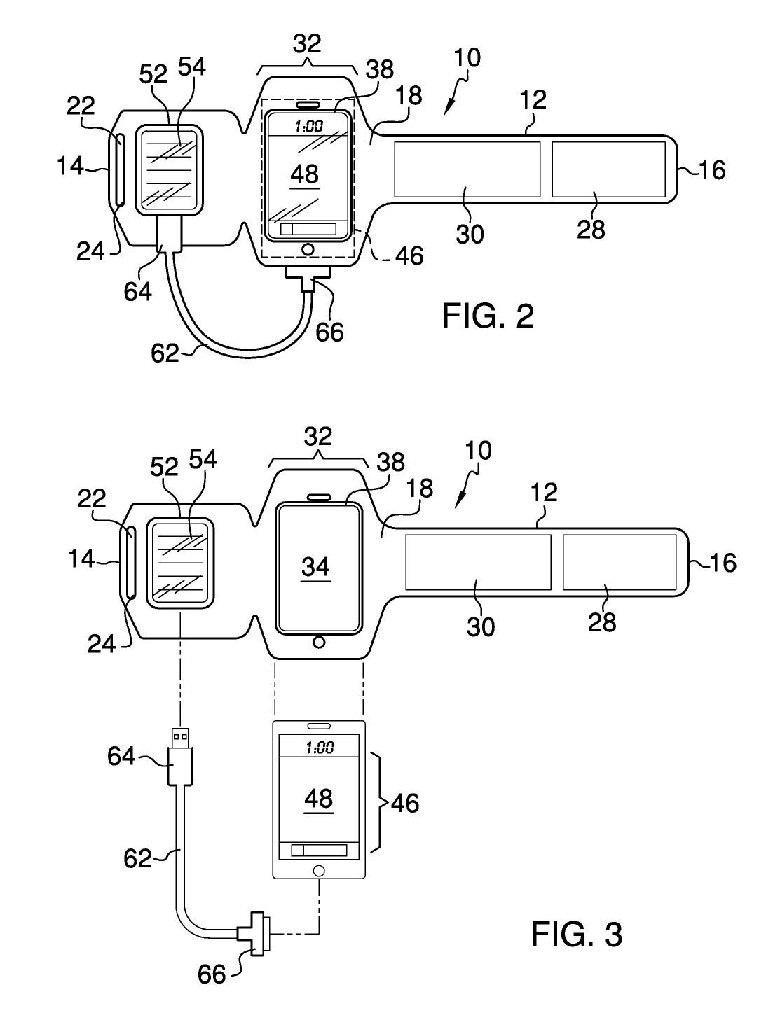

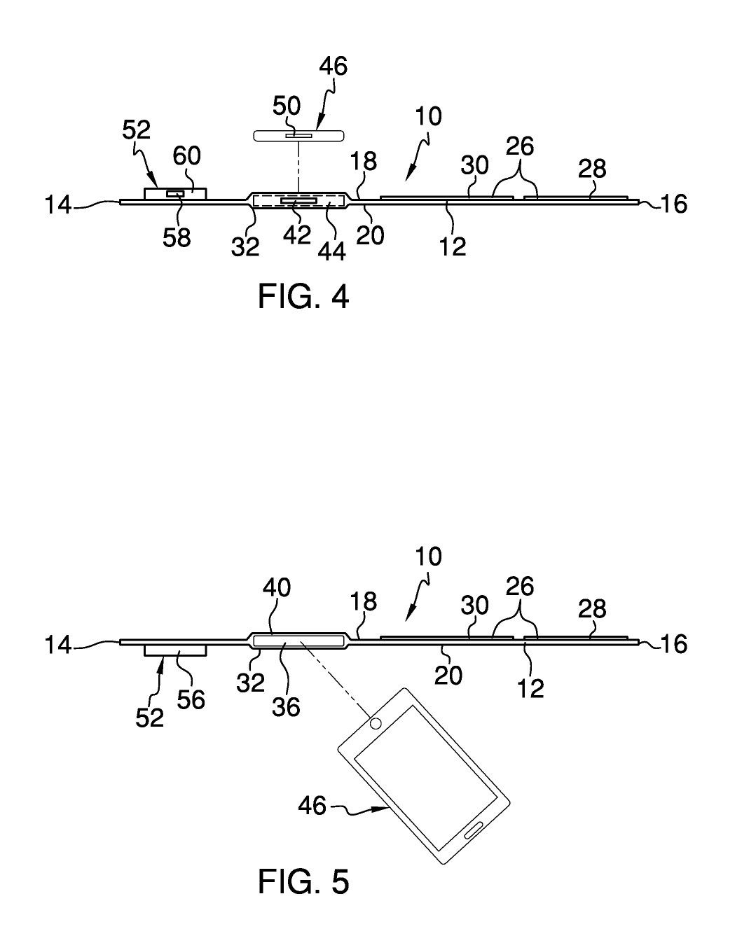

With reference now to FIGS. 1 through 5 of the drawings, a new apparatus for securing an electronic device to the body of a user embodying the principles and concepts of an embodiment of the present invention and generally designated by the reference numeral 10 will be described.

As best illustrated in FIGS. 1 through 5, the apparatus 10 is generally includes an elongated band 12, a band end engagement mechanism 22, a solar energy operated power generator 52, a pouch 32, and an electrical cable 62.

The elongated band 12 has opposed first and second ends 14 and 16, an exterior surface 18 and an interior surface 20. The elongated band 12 is adapted to be wrapped around and encircle a user's body portion, such as, for example, a wrist or an arm, with the exterior surface 18 facing in an outward direction from the body of the user and the interior surface 20 facing in an inward direction towards the body of the user. The elongated band 12 is formed of a flexible material permitting the band to wrap around the user. The flexible material may be machine-washable and/or waterproof.

Disposed proximate to the first end 14 of the elongated band 12 is a band end engagement mechanism 22 that operates to detachably secure together the first end 14 and the second end 16 of the elongated band 12. In an embodiment, the first end 14 of the elongated band 12 may include a slot or opening 24 through which the second end 16 of the elongated band 12 may be threadably inserted and secured from withdrawal to secure the first and second ends 14 and 16 together. In another embodiment, the band end engagement mechanism 22 may include a touch fastener 26 including a first fastener element 28 mounted on the exterior surface 18 of the elongated band 12 and proximate the second end 16 thereof and a second fastener element 30 mounted on the exterior surface 18 of the elongated band 12 between the pouch 32 and the first fastener element 28.

The pouch 32 is disposed on the exterior surface 18 of the elongated band 12, and includes an interior cavity 34, a pouch opening 36 into the interior cavity for removable inserting an electronic device into the interior cavity 34, and a window 38 for viewing and/or interacting with an electronic device positioned within the internal cavity 34. In an embodiment, the pouch opening 36 is located along a top edge surface 40 of the pouch 32. The interior cavity 34 is configured to removably receive an electronic device 46 such as a cell phone, a smart phone, a portable music player, or a digital camera and conform to the shape of the electronic device once inserted. The window 38 located along the exterior surface 18 of the elongated band 12, wherein a touchscreen 48 of the electronic device 46 is made readily accessible to the user. The pouch 32 further includes a slot 42 located along the bottom edge 44 of the pouch 32, wherein an electrical connector receiver 50 of the electronic device 46 is made readily accessible to an electrical connector.

The solar energy operated power generator 52 is supported by the elongated band 12 and includes a solar panel 54 that is disposed to face outwardly from the exterior surface 18 of the elongated band 12 to permit exposure to sunlight when the elongated band 12 is secured to a user. The solar energy operated power generator 52 further includes a top edge surface 56 and a bottom edge surface 60, wherein an electrical connector receiver 56 located along the bottom edge surface 60 of the solar energy operated power generator 52 is made readily accessible to an electrical connector. The solar energy operated power generator 52 operates to generate electrical power that is used to power and/or recharge the batteries of the electronic device 46 that is electrically connected to the solar energy operated power generator 52. It should be noted, however, that solar energy operated power generator devices are well known in the art, and the details of which form no part of the present invention. Thus, a complete description of the construction and operation is not required herein for one of ordinary skill in the art to understand and implement the embodiments of the invention.

The electrical cable 62 has a first and second electrical connector 64 and 66 located on opposed ends of the electrical connector cable. The first electrical connector 64 is adapted to be connectably received by the electrical connector receiver of the solar energy operated power generator 52. First electrical connector 64 may be a USB type connector. The second electrical connector 66 is adapted to be connectably received by the electrical connector receiver of the electronic device 46. When the solar energy operated power generator 52 has generated electrical power, it transmits electrical power from the solar energy operated power generator 52 to the first electrical connector 64. The electrical power is then transmitted across the electrical cable 62 to the second electrical connector 66, which is connectably received by the electrical connector receiver 50 of the electronic device 46.

The solar energy operated power generator 40 may also include a rechargeable battery (not shown) to provide a source of electrical power to the electronic 46 device during periods of low light that is insufficient to permit the generator to produce electrical power to operate and/or charge the electronic device. In such an embodiment, the solar energy operated power generator may alternatively be connected to a source of line power, such as, for example, a household electrical outlet to charge the rechargeable battery thereof.

Although, while not depicted, in other embodiments, the elongated band 12 may have imprinted thereupon, or otherwise include, various aesthetic designs, patterns, or colors, as desired.

In operation, it can now be understood that a user, such as a jogger; hiker; or biker may be able to secure their electronic device 28 to their person, without the need to hold it during rigorous physical activity. The user may removably insert their electronic device 46 into the pouch 32 of the elongated band 12 and detachably secure the first end 14 and the second end 16 of the elongated band 12 by threadably inserting the second end 16 of the elongated band through the band end engagement mechanism 22, and further, securing the elongated band 12 using touch fasteners. The user may then connect the electronic device 46 to the solar energy operated power generator 52 by inserting the first electrical connector 64 of the electrical cable 62 into the electrical connector receiver 58 of the solar energy operated power generator 52 and inserting the second electrical connector 66 of the electrical cable 62 into the electrical connector receiver 50 of the electronic device 46. After the user has secured the elongated band 12 to their person and has begun their physical activity, the solar panel will absorb sunlight and generate electrical power to charge and/or power the electronic device 46.

Thus, an important aspect of the invention is found in the solar energy operated power generator 52, in that is provides an environmentally-friendly and renewable means to maintain a constant charge to the user's electronic device 46, particularly while the electronic device 46 is in use.

A number of embodiments of the present invention have been described. Nevertheless, it will be understood that various modifications may be made without departing from the spirit and scope of the invention.

What is claimed is:

1. An apparatus for securing an electronic device to the body of a user, the apparatus comprising:
an elongated band having opposed first and second ends, an interior surface, and an exterior surface;
a band end engagement mechanism disposed proximate to said first end of said elongated band and operating to detachably secure together said first and second ends of said elongated band;
a pouch for receiving an electronic device disposed on said exterior surface of said elongated band, said pouch including an internal cavity that removably receives and conforms to the shape of an electronic device disposed therein, and a window registered with a control screen of the electronic device and permitting user access through said window to the control screen when said electronic device is received by said internal cavity;
a solar energy operated power generator on said elongated band; and
an electrical connector cable configured to connect said solar energy operated power generator to an electronic device to provide electrical energy from said solar energy operated power generator to the electronic device.

2. An apparatus for holding an electronic device and securing the electronic device to the body of a user, said apparatus comprising:
an elongated band configured to encircle a body portion of a user, said elongated band having opposed first and second ends and an exterior surface that faces in a general direction outwardly from the body of a user when said elongated band is secured to the user;
a band end engagement mechanism disposed proximate to said first end of said elongated band and operating to detachably secure together said first and second ends of said elongated band;
a pouch for receiving an electronic device on said elongated band, said pouch defining an interior cavity and an opening into said interior cavity through which an electronic device may be passed to insert said electronic device into said interior cavity, said interior cavity removably receiving and conforming to an electronic device disposed therein;
a solar energy operated power generator on said exterior surface of said elongated band and operating to provide electrical power for operating the electronic device and charging a rechargeable battery of the electronic device; and
an electrical cable connectable at one end to said solar energy operated power generator and connectable at a second end to an electrical connector of the electronic device for electrically connecting the electronic device and said solar energy operated power generator to provide electrical power to the electronic device generated by said solar energy operated power generator.

3. The band according to claim 2, wherein said pouch further includes a window registered with a control screen of said electronic device and permitting user access through said window to the control screen when the electronic device is received by said internal cavity.

4. An apparatus for holding an electronic device and securing said electronic device to the body of a user, said apparatus comprising:
an elongated band configured to encircle a body portion of a user, said elongated band having opposed first and second ends and an exterior surface that faces in a general direction outwardly from the body of a user when said elongated band is secured to the user;
a band end engagement mechanism disposed proximate to said first end of said elongated band and operating to detachably secure together said first and second ends of said elongated band;
a pouch on said elongated band, said pouch defining an interior cavity and an opening into said interior cavity; through which an electronic device may be passed to insert said electronic device into said interior cavity, said interior cavity removably receiving and conforming to an electronic device disposed therein;
an electronic device removably passed through said opening in said pouch into said interior cavity, wherein said interior cavity conforms to said electronic device disposed therein;
a solar energy operated power generator on said exterior surface of said elongated band and operating to provide electrical power for operating said electronic device and charging a rechargeable battery of said electronic device; and
an electrical cable having a first electrical connector at a first end of said electrical cable connectable to an electrical connector receiver of said solar energy operated power generator and a second electrical connector at a second end of said electrical cable connectable to an electrical connector receiver of said electronic device for electrically connecting said electronic device and said solar energy operated power generator to provide electrical power generated by said solar energy operated power generator from said solar energy operated power generator to said electronic device.
